(19) United States
(12) Patent Application Publication
(10) Pub. No.: US 2022/0382465 A1
(43) Pub. Date: Dec. 1, 2022

(54) VELOCITY BASED WRITE DISTURB REFRESH

(71) Applicant: Intel Corporation, Santa Clara, CA (US)

(72) Inventors: Rakan Maddah, Portland, OR (US); Jason Gayman, Cameron Park, CA (US); Arjun Kripanidhi, Mountain View, CA (US); Wilson Fang, El Dorado Hills, CA (US); Prashant S. Damle, Portland, OR (US)

(21) Appl. No.: 17/818,161

(22) Filed: Aug. 8, 2022

(51) Int. Cl. G06F 3/06

(52) U.S. Cl. CPC G06F 3/0619; G06F 3/0679; G06F 3/0653

(57) ABSTRACT

Systems, apparatuses and methods may provide for technology that determines a write-to-write delay with respect to a memory cell, wherein one or more neighboring cells are adjacent to the memory cell and controls a write disturb refresh rate of the one or more neighboring cells based on the write-to-write delay. In one example, the technology increments a write counter corresponding to the memory cell by a first value if the write-to-write delay exceeds a delay threshold and increments the write counter by a second value if the write-to-write delay does not exceed the delay threshold, wherein the second value is greater than the first value, and wherein the write disturb refresh rate is controlled based on the write counter.

### TECHNICAL FIELD

Embodiments generally relate to non-volatile memory (NVM). More particularly, embodiments relate to velocity based write disturbance (“disturb”) refresh operations in NVM.

### BACKGROUND

Writing to a non-volatile memory (NVM) cell typically results in thermal crosstalk to neighboring cells and potential data loss in the neighboring cells. To prevent the loss of data, memory controllers may issue periodic write operations at a constant rate to the neighboring cells (e.g., neighboring addresses) of a target cell (e.g., target address being actively written to), wherein the periodic write operations refresh and retain the state of the neighboring cells. This approach is commonly known as “write disturb” refresh.

Scaling NVM technologies are expected to improve the write bandwidth (BW). At the same time, the scaling is expected to increase thermal crosstalk, which poses challenges for memory controllers to maintain a sufficient write disturb refresh rate without limiting the write bandwidth.

### BRIEF DESCRIPTION OF THE DRAWINGS

The various advantages of the embodiments will become apparent to one skilled in the art by reading the following specification and appended claims, and by referencing the following drawings, in which:

FIG. 1 is an illustration of an example of a target memory cell and neighboring memory cells according to an embodiment;

FIG. 2 is a plot of an example of write disturb capability as a function of write-to-write delay to the same address according to an embodiment;

FIG. 3 is a flowchart of an example of a method of operating a memory controller according to an embodiment;

FIG. 4 is a flowchart of an example of a more detailed method of operating a memory controller according to an embodiment;

FIG. 5 is a plot of an example of a write-to-write delay to the same address distribution according to an embodiment;

FIG. 6 is a block diagram of an example of a computing system according to an embodiment; and

FIG. 7 is an illustration of an example of a semiconductor package according to an embodiment.

### DESCRIPTION OF EMBODIMENTS

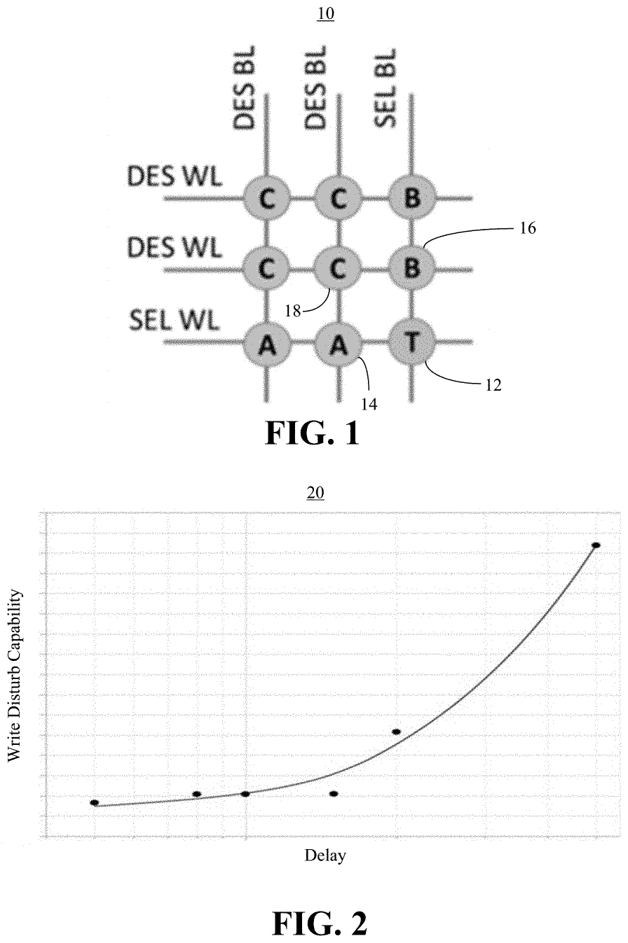

Turning now to FIG. 1, a memory array 10 is shown in which a target cell 12 (T), is adjacent to neighboring cells including an unselected cell 14 (A) that shares a selected word-line (SEL WL) with the target cell 12, an unselected cell 16 (B) that shares a selected bit-line (SEL BL) with the target cell 12, and an unselected cell 18 (C) on deselected word-lines (DES WL) and deselected bit-lines (DES BL). In general, writing to the target cell 12 results in thermal crosstalk to the unselected cells 14, 16, 18, wherein the thermal crosstalk may lead to data loss in the unselected cells 14, 16, 18. Moreover, when write operations (“writes”) to the target cell 12 occur within a short time from one another, the thermal crosstalk and data loss may increase in severity. As will be discussed in greater detail, technology described herein leverages information regarding the write-to-write delay for the target cell 12 to control the write disturb refresh rate of the unselected cells 14, 16, 18. As a result, enhanced performance may be achieved in terms of reduced data loss and/or increased bandwidth.

FIG. 2 shows a plot 20 of write disturb capability (e.g., number of writes) of neighboring cells as a function of write-to-write delay to the same address/target cell. The plot 20 demonstrates that as the write-to-write delay increases, the write disturb capability also increases. Embodiments increase the write disturb refresh rate for the neighboring cells when the write-to-write delay for the target cell is relatively low and decrease the write disturb refresh rate for the neighboring cells when the write-to-write delay for the target cell is relatively high.

Certain NVM technologies may specify a demarcation voltage (VDM) when issuing read/write operations, wherein the VDM level is selected based on the elapsed time from the last write to the address. To this end, memory controllers may implement a “drift tracker” module that logs the timestamp of the last write to an address. This timestamp may be used to derive an optimal VDM when a new input/output (TO) operation is issued to the same address within the memory module.

Embodiments manage write disturb (WD) refreshes through a dedicated write counter in metadata that is incremented based on the demarcation voltage with which the write is issued. Given that WD capability is based on the write-to-write delay to the same address as shown in the plot 20, technology described herein increments the WD write count at relatively high “velocity” (e.g., large increment value) if the incoming write VDM indicates a short write-to-write delay and a low velocity (e.g., small increment value) if the incoming write VDM indicates a longer delay between subsequent writes.

Velocity based WD enables thermal crosstalk to be managed in an effective way that conforms to the workloads being run. In practice, multiple back-to-back writes to the same address at a short delay in the microsecond (μS) range are not common. Accordingly, velocity WD takes advantage of that fact by slowing the WD refresh rate when a faster WD refresh rate is not needed (e.g., and potentially wasteful of bandwidth resources).

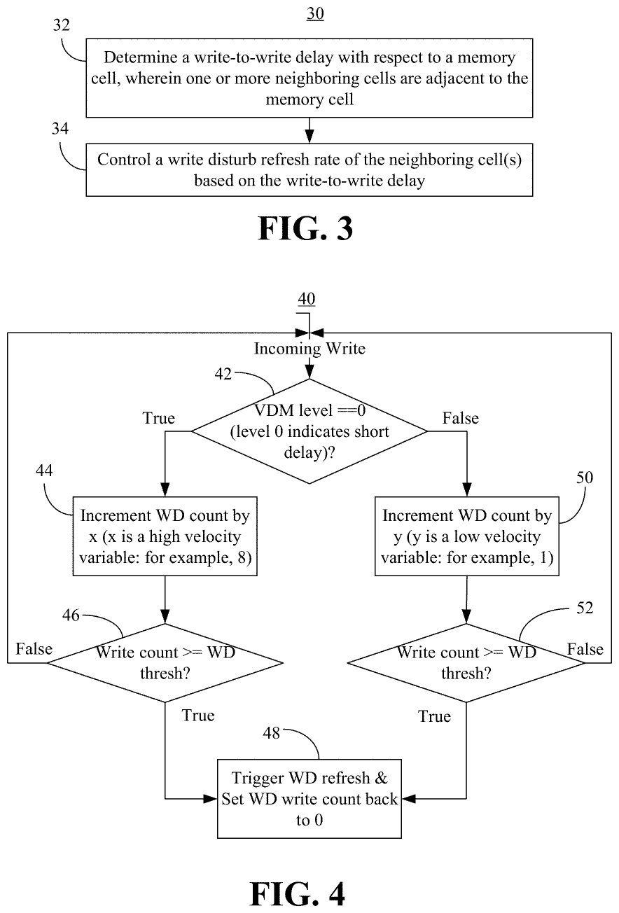

FIG. 3 shows a method 30 of operating a memory controller. The method 30 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic (e.g., configurable hardware), fixed-functionality logic (e.g., fixed-functionality hardware), or any combination thereof. Examples of configurable logic include suitably configured programmable logic arrays (PLAs), field programmable gate arrays (FPGAs), complex programmable logic devices (CPLDs), and general purpose microprocessors. Examples of fixed-functionality logic include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Illustrated processing block 32 determines a write-to-write delay with respect to a memory cell, wherein one or more neighboring cells are adjacent to the memory cell. In one example, block 32 determines a demarcation voltage associated with the memory cell. Block 34 controls a write disturb refresh rate of the neighboring cell(s) based on the write-to-write delay. As already noted, block 34 may increase the write disturb refresh rate for the neighboring cells when the write-to-write delay for the target cell is relatively low and decrease the write disturb refresh rate for the neighboring cells when the write-to-write delay for the target cell is relatively high. Increasing the write disturb refresh rate when the write-to-write delay is low prevents data loss in the neighboring cells and therefore increases the write disturb capability of the neighboring cells. Decreasing the write disturb refresh rate when the write-to-write delay is high increases bandwidth. The method 30 therefore enhances performance at least to the extent that controlling the write disturb refresh rate based on the write-to-write delay increases write disturb capability, prevents data loss and/or increases bandwidth.

FIG. 4 shows a more detailed method 40 of operating a memory controller. The method 40 may be implemented in one or more modules as a set of logic instructions stored in a machine- or computer-readable storage medium such as RAM, ROM, PROM, firmware, flash memory, etc., in hardware, or any combination thereof.

As already noted, embodiments take advantage of the demarcation voltage (VDM) level that is sent with write/read operations in certain NVM technologies. The VDM level is selected based on the last write timestamp to an address. Memory controllers deploy a “drift tracker” module to track write stamps and derive VDM levels. Accordingly, the technology described herein augments the metadata of addresses by a dedicated write disturb write counter. This counter is incremented based on the “velocity” on the incoming write relative to the previous write as derived from the VDM level. If the write delay is short, then the counter is incremented by a large value (e.g., eight) to indicate a write that caused a thermal disturbance. Conversely, if the incoming VDM indicates a long delay, then the counter is incremented by a small value (e.g., one) because write is benign when it comes to thermal disturbance. The nominal WD capability will be multiplied by the velocity factor of the low VDM counter increase and set as a trigger threshold.

For example, the WD capability of a memory module may be assumed to be “z”, wherein a VDM level zero indicates a short write delay and a VDM level one indicates a long write delay. In such a case, velocity based WD manages the write count as follows:
Incoming write with VDM0, increment WD write counter by x
Incoming write with VDM1, increment WD write counter by y (y<x)
Set WD memory controller trigger threshold to x*z
Example: x=8, y=1, z=512 and WD threshold=4096

Illustrated processing block 42 therefore determines whether the VDM level is zero (e.g., delay threshold) in response to an incoming write operation, wherein a VDM level of zero indicates a relatively short write-to-write delay. If it is determined at block 42 that the VDM level is zero, block 44 increments the WD write count by x (e.g., a high velocity variable such as eight). A determination is then made at block 46 as to whether a condition exists in which the write count has exceeded a WD threshold (e.g., trigger threshold). If so, block 48 initiates/triggers a WD refresh operation in the neighboring cell(s) in response to the condition. Block 48 may also reset the write counter in response to the refresh operation.

If it is determined at block 42 that the VDM level is not zero, block 50 increments the WD write count by y (e.g., a low velocity variable such as one). A determination is then made at block 52 as to whether the condition exists in which the write count has exceeded the WD threshold. If so, block 48 initiates/triggers a WD refresh operation and resets the write counter. If it is determined at block 46 or block 52 that the write count has not exceeded the WD threshold, the illustrated method 40 returns to block 42.

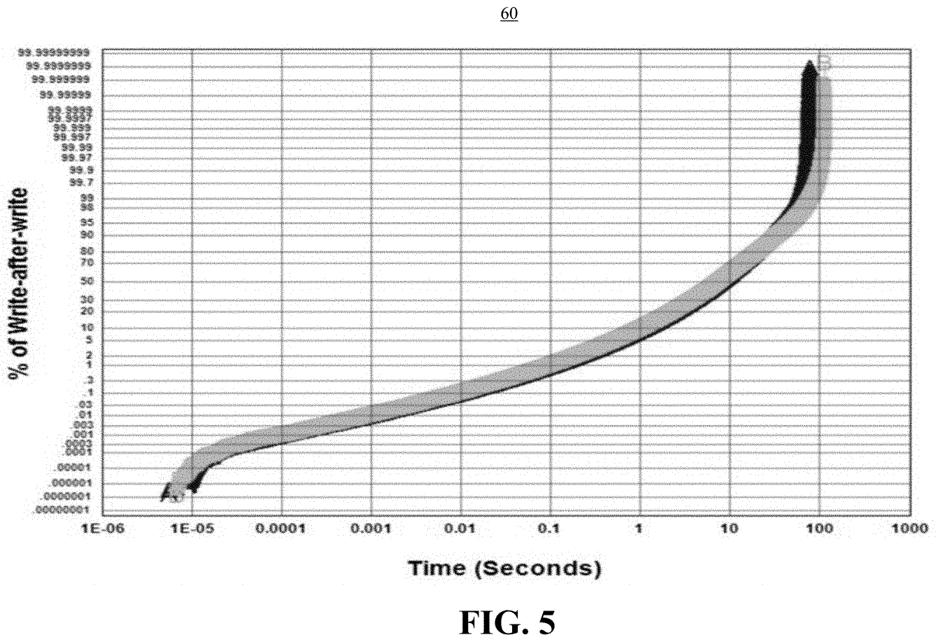

Turning now to FIG. 5, a plot 60 (e.g., showing the distribution of write-to-write accesses to the same address relative to the delay) demonstrates that most of the accesses have a relatively large write-to-write delay. Analysis of write disturb trigger rates based on this data shows that the WD refresh rate can be increased by ˜8× through velocity based WD relative to conventional solutions in which the memory controller issues refreshes at a high rate unnecessarily for typical workloads. For workloads with only short write-to-write delay to the same address, the velocity scheme may be refreshing at a similar rate to conventional approaches. Such workloads are atypical and viral, however, and do not account for the majority of typical accesses.

As already noted, the scaling of NVM technologies will likely result in lower write disturb capability while the write bandwidth will increase. This condition leads to a higher WD trigger rate and poses challenges for the memory controller to keep up with write disturb events. Typically, the memory controller may monitor the WD trigger rate and throttle write bandwidth when the memory controller cannot maintain pace with the write disturb trigger rates.

Additionally, a significant amount of bandwidth can be recovered if the WD refresh threshold is set to a larger value. With the conventional WD refresh management approach, the WD is set to a relatively low value based on the component capability. With velocity based refresh, however, a larger WD refresh threshold value results in bandwidth improvement for typical and realistic workloads.

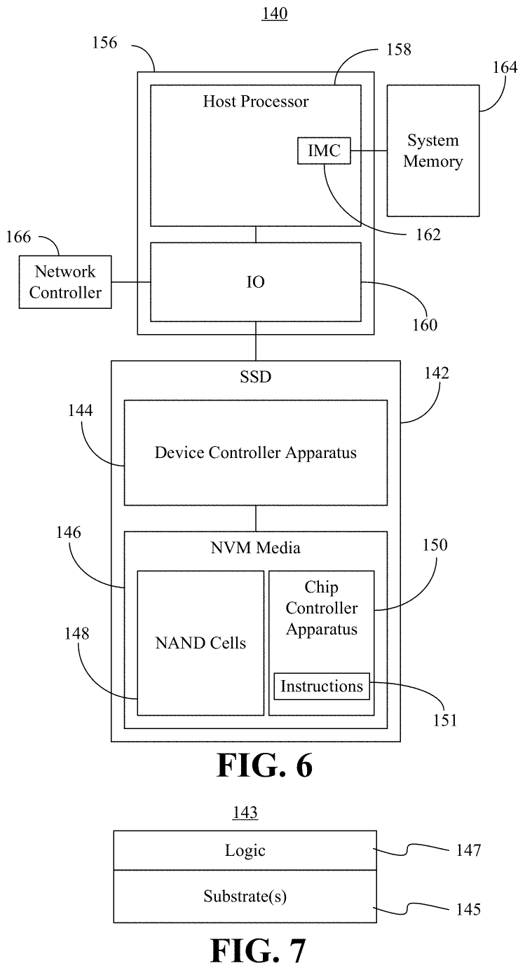

FIG. 6 shows a computing system 140. The system 140 may be part of a server (e.g., datacenter, cloud computing infrastructure), desktop computer, notebook computer, tablet computer, convertible tablet, smart television (TV), personal digital assistant (PDA), mobile Internet device (MID), smart phone, wearable device, media player, vehicle, robot, Internet of Things (IoT) device, drone, autonomous vehicle, etc., or any combination thereof. In the illustrated example, an input/output (IO) module 160 is communicatively coupled to a solid state drive (SSD) 142 and a network controller 166 (e.g., wired, wireless).

The system 140 may also include a host processor 158 (e.g., central processing unit/CPU) that includes an integrated memory controller (WIC) 162, wherein the illustrated WIC 162 communicates with a system memory 164 (e.g., DRAM) over a bus or other suitable communication interface. The host processor 158 and the IO module 160 are integrated onto a shared semiconductor die 156 in a system on chip (SoC) architecture.

The SSD 142 may include a device controller apparatus 144 coupled to non-volatile memory (NVM) media 146 such as, for example, a three-dimensional (3D) crosspoint memory device including single- or multi-level phase change memory. The 3D crosspoint memory may comprise a transistor-less stackable crosspoint architecture in which memory cells sit at the intersection of word-lines and bit-lines and are individually addressable and in which bit storage is based on a change in bulk resistance. In an embodiment, the NVM media 146 includes a chip controller apparatus 150 (e.g., memory controller) coupled to a plurality of NAND cells 148 (e.g., including a targeted memory cell and one or more neighboring cells). In an embodiment, the chip controller apparatus 150 includes a set of instructions 151 to implement one or more aspects of the method 30 (FIG. 3) and/or the method 40 (FIG. 4), already discussed. Thus, execution of the instructions 151 may cause the chip controller apparatus 150 to determine a write-to-write delay with respect to the memory cell and control a write disturb refresh rate of the one or more neighboring cells based on the write-to-write delay. The chip controller apparatus 150 and/or the computing system 140 are therefore considered performance-enhanced at least to the extent that controlling the write disturb refresh rate based on the write-to-write delay increases write disturb capability, prevents data loss and/or increases bandwidth.

FIG. 7 shows a semiconductor apparatus 143 (e.g., chip, die) that includes one or more substrates 145 (e.g., silicon, sapphire, gallium arsenide) and logic 147 (e.g., transistor array and other integrated circuit/IC components) coupled to the substrate(s) 145. The logic 147, which may be implemented at least partly in configurable and/or fixed-functionality hardware, may generally implement one or more aspects of the method 30 (FIG. 3) and/or the method 40 (FIG. 4), already discussed. Thus, the logic 147 may determine a write-to-write delay with respect to a memory cell, wherein one or more neighboring cells are adjacent to the memory cell, and control a write disturb refresh rate of the one or more neighboring cells based on the write-to-write delay.

In one example, the logic 147 includes transistor channel regions that are positioned (e.g., embedded) within the substrate(s) 145. Thus, the interface between the logic 147 and the substrate(s) 145 may not be an abrupt junction. The logic 147 may also be considered to include an epitaxial layer that is grown on an initial wafer of the substrate(s) 145.

### Additional Notes and Examples

Example 1 includes a performance-enhanced memory controller comprising one or more substrates and logic coupled to the one or more substrates, wherein the logic is implemented at least partly in one or more of configurable or fixed-functionality hardware, the logic to determine a write-to-write delay with respect to a memory cell, wherein one or more neighboring cells are adjacent to the memory cell and control a write disturb refresh rate of the one or more neighboring cells based on the write-to-write delay.

Example 2 includes the memory controller of Example 1, wherein the logic is further to increment a write counter corresponding to the memory cell by a first value if the write-to-write delay exceeds a delay threshold, and increment the write counter by a second value if the write-to-write delay does not exceed the delay threshold, wherein the second value is greater than the first value, and wherein the write disturb refresh rate is controlled based on the write counter.

Example 3 includes the memory controller of Example 2, wherein the logic is further to detect a condition in which the write counter exceeds a trigger threshold, and initiate a refresh operation in the one or more neighboring cells in response to the condition.

Example 4 includes the memory controller of Example 2, wherein the logic is further to reset the write counter in response to a refresh operation in the one or more neighboring cells.

Example 5 includes the memory controller of any one of Examples 1 to 4, wherein to determine the write-to-write delay, the logic is to determine a demarcation voltage associated with the memory cell.

Example 6 includes at least one computer readable storage medium comprising a set of instructions, which when executed by a memory controller, cause the memory controller to determine a write-to-write delay with respect to a memory cell, wherein one or more neighboring cells are adjacent to the memory cell, and control a write disturb refresh rate of the one or more neighboring cells based on the write-to-write delay.

Example 7 includes the at least one computer readable storage medium of Example 6, wherein the instructions, when executed, further cause the memory controller to increment a write counter corresponding to the memory cell by a first value if the write-to-write delay exceeds a delay threshold, and increment the write counter by a second value if the write-to-write delay does not exceed the delay threshold, wherein the second value is greater than the first value, and wherein the write disturb refresh rate is controlled based on the write counter.

Example 8 includes the at least one computer readable storage medium of Example 7, wherein the instructions, when executed, further cause the memory controller to detect a condition in which the write counter exceeds a trigger threshold, and initiate a refresh operation in the one or more neighboring cells in response to the condition.

Example 9 includes the at least one computer readable storage medium of Example 7, wherein the instructions, when executed, further cause the memory controller to reset the write counter in response to a refresh operation in the one or more neighboring cells.

Example 10 includes the at least one computer readable storage medium of any one of Examples 6 to 9, wherein to determine the write-to-write delay, the instructions, when executed, further cause the memory controller to determine a demarcation voltage associated with the memory cell.

Example 11 includes a computing system comprising a non-volatile memory including a memory cell and one or more neighboring cells adjacent to the memory cell, and a memory controller including logic coupled to one or more substrates, the logic to determine a write-to-write delay with respect to the memory cell, and control a write disturb refresh rate of the one or more neighboring cells based on the write-to-write delay.

Example 12 includes the computing system of Example 11, wherein the logic is further to increment a write counter corresponding to the memory cell by a first value if the write-to-write delay exceeds a delay threshold, and increment the write counter by a second value if the write-to-write delay does not exceed the delay threshold, wherein the second value is greater than the first value, and wherein the write disturb refresh rate is controlled based on the write counter.

Example 13 includes the computing system of Example 2, wherein the logic is further to detect a condition in which the write counter exceeds a trigger threshold, and initiate a refresh operation in the one or more neighboring cells in response to the condition.

Example 14 includes the computing system of Example 12, wherein the logic is further to reset the write counter in response to a refresh operation in the one or more neighboring cells.

Example 15 includes the computing system of any one of Examples 11 to 14, wherein to determine the write-to-write delay, the logic is to determine a demarcation voltage associated with the memory cell.

Example 16 includes a method of operating a performance-enhanced memory controller, the method comprising determining a write-to-write delay with respect to a memory cell, wherein one or more neighboring cells are adjacent to the memory cell, and controlling a write disturb refresh rate of the one or more neighboring cells based on the write-to-write delay.

Example 17 includes the method of Example 16, further including incrementing a write counter corresponding to the memory cell by a first value if the write-to-write delay exceeds a delay threshold, and incrementing the write counter by a second value if the write-to-write delay does not exceed the delay threshold, wherein the second value is greater than the first value, and wherein the write disturb refresh rate is controlled based on the write counter.

Example 18 includes the method of Example 17, further including detecting a condition in which the write counter exceeds a trigger threshold, and initiating a refresh operation in the one or more neighboring cells in response to the condition.

Example 19 includes the method of Example 17, further including resetting the write counter in response to a refresh operation in the one or more neighboring cells.

Example 20 includes the method of any one of Examples 16 to 19, wherein determining the write-to-write delay includes determining a demarcation voltage associated with the memory cell.

Example 21 includes an apparatus comprising means for performing the method of any one of Examples 16 to 20.

The technology described herein takes into consideration the dependency of thermal stress on the delay among write operations and does not force refresh writes to be issued at a rate that assumes the worst thermal stress capability. For example, the technology manages write disturbances effectively in accordance to the technology behavior where only short delay writes cause WD stress. The technology also increases the WD refresh rate by at least 8× allowing for up to ˜5% performance gains. In addition, the technology enables a memory controller to maintain pace better with WD refresh rate at high write bandwidth without limiting the bandwidth.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A memory controller comprising:
one or more substrates; and
logic coupled to the one or more substrates, wherein the logic is implemented at least partly in one or more of configurable or fixed-functionality hardware, the logic to:
determine a write-to-write delay with respect to a memory cell, wherein one or more neighboring cells are adjacent to the memory cell; and
control a write disturb refresh rate of the one or more neighboring cells based on the write-to-write delay.

2. The memory controller of claim 1, wherein the logic is further to:
increment a write counter corresponding to the memory cell by a first value if the write-to-write delay exceeds a delay threshold; and
increment the write counter by a second value if the write-to-write delay does not exceed the delay threshold, wherein the second value is greater than the first value, and wherein the write disturb refresh rate is controlled based on the write counter.

3. The memory controller of claim 2, wherein the logic is further to:
detect a condition in which the write counter exceeds a trigger threshold; and
initiate a refresh operation in the one or more neighboring cells in response to the condition.

4. The memory controller of claim 2, wherein the logic is further to reset the write counter in response to a refresh operation in the one or more neighboring cells.

5. The memory controller of claim 1, wherein to determine the write-to-write delay, the logic is to determine a demarcation voltage associated with the memory cell.

6. At least one computer readable storage medium comprising a set of instructions, which when executed by a memory controller, cause the memory controller to:
determine a write-to-write delay with respect to a memory cell, wherein one or more neighboring cells are adjacent to the memory cell; and
control a write disturb refresh rate of the one or more neighboring cells based on the write-to-write delay.

7. The at least one computer readable storage medium of claim 6, wherein the instructions, when executed, further cause the memory controller to:
increment a write counter corresponding to the memory cell by a first value if the write-to-write delay exceeds a delay threshold; and
increment the write counter by a second value if the write-to-write delay does not exceed the delay threshold, wherein the second value is greater than the first value, and wherein the write disturb refresh rate is controlled based on the write counter.

8. The at least one computer readable storage medium of claim 7, wherein the instructions, when executed, further cause the memory controller to:
detect a condition in which the write counter exceeds a trigger threshold; and
initiate a refresh operation in the one or more neighboring cells in response to the condition.

9. The at least one computer readable storage medium of claim 7, wherein the instructions, when executed, further cause the memory controller to reset the write counter in response to a refresh operation in the one or more neighboring cells.

10. The at least one computer readable storage medium of claim 6, wherein to determine the write-to-write delay, the instructions, when executed, further cause the memory controller to determine a demarcation voltage associated with the memory cell.

11. A computing system comprising:
a non-volatile memory including a memory cell and one or more neighboring cells adjacent to the memory cell; and
a memory controller including logic coupled to one or more substrates, the logic to:
determine a write-to-write delay with respect to the memory cell, and
control a write disturb refresh rate of the one or more neighboring cells based on the write-to-write delay.

12. The computing system of claim 11, wherein the logic is further to:
increment a write counter corresponding to the memory cell by a first value if the write-to-write delay exceeds a delay threshold, and
increment the write counter by a second value if the write-to-write delay does not exceed the delay threshold, wherein the second value is greater than the first value, and wherein the write disturb refresh rate is controlled based on the write counter.

13. The computing system of claim 2, wherein the logic is further to:
detect a condition in which the write counter exceeds a trigger threshold, and
initiate a refresh operation in the one or more neighboring cells in response to the condition.

14. The computing system of claim 12, wherein the logic is further to reset the write counter in response to a refresh operation in the one or more neighboring cells.

15. The computing system of claim 11, wherein to determine the write-to-write delay, the logic is to determine a demarcation voltage associated with the memory cell.

16. A method comprising:
determining a write-to-write delay with respect to a memory cell, wherein one or more neighboring cells are adjacent to the memory cell; and
controlling a write disturb refresh rate of the one or more neighboring cells based on the write-to-write delay.

17. The method of claim 16, further including:
incrementing a write counter corresponding to the memory cell by a first value if the write-to-write delay exceeds a delay threshold; and
incrementing the write counter by a second value if the write-to-write delay does not exceed the delay threshold, wherein the second value is greater than the first value, and wherein the write disturb refresh rate is controlled based on the write counter.

18. The method of claim 17, further including:
detecting a condition in which the write counter exceeds a trigger threshold; and
initiating a refresh operation in the one or more neighboring cells in response to the condition.

19. The method of claim 17, further including resetting the write counter in response to a refresh operation in the one or more neighboring cells.

20. The method of claim 16, wherein determining the write-to-write delay includes determining a demarcation voltage associated with the memory cell.
